(19) United States
(12) Patent Application Publication
(10) Pub. No.: US 2024/0375212 A1
(43) Pub. Date: Nov. 14, 2024

(54) WAFER DICING DEVICES AND METHODS OF WAFER DICING

(71) Applicant: Yangtze Memory Technologies Co., Ltd., Wuhan (CN)

(72) Inventors: Wei Xie, Wuhan (CN); Ping Mo, Wuhan (CN); Lei Liu, Wuhan (CN); Zhong Lv, Wuhan (CN); ZhiLiang Xia, Wuhan (CN); ZongLiang Huo, Wuhan (CN)

(21) Appl. No.: 18/514,705

(22) Filed: Nov. 20, 2023

Related U.S. Application Data
(63) Continuation of application No. PCT/CN2023/093949, filed on May 12, 2023.

(51) Int. Cl. B23K 26/06; H01L 21/304; H01L 21/683

(52) U.S. Cl. CPC B23K 26/0648; B23K 26/0643; H01L 21/304; H01L 21/6835; H01L 2221/68327

(57) ABSTRACT

Examples of the present disclosure provide a wafer dicing device and a method of wafer dicing, the wafer dicing device including: a bearing platform, a first dicing sub device and a second dicing sub device, wherein the bearing platform is configured to bear the wafer to be diced, the first dicing sub device is configured to dice the wafer to be diced from a first side, and the second dicing sub device is configured to dice the wafer to be diced from a second side, the first side and the second side being opposite sides of the bearing platform in a first direction, the first direction being a direction of the thickness of the bearing platform.

### REFERENCE TO RELATED APPLICATION

This application is a continuation of International Patent Application PCT/CN2023/093949, filed on May 12, 2023, which is hereby incorporated by reference in its entirety.

### TECHNICAL FIELD

The present disclosure relates to wafer dicing devices and methods of wafer dicing.

### BACKGROUND

During a semiconductor manufacturing process, firstly forming a plurality of chips on a wafer using semiconductor processes, then dicing the wafer into individual chips using dicing process and finally packaging these chips to obtain usable semiconductor devices.

### BRIEF DESCRIPTION OF ACCOMPANYING DRAWINGS

FIG. 1 is a first structural diagram of a wafer dicing device in accordance with an example of the present disclosure;

FIG. 2 is a structural diagram of a wafer to be diced in accordance with an example of the present disclosure;

FIG. 3 is a second structural diagram of a wafer dicing device in accordance with an example of the present disclosure;

FIG. 4 is a third structural diagram of a wafer dicing device in accordance with an example of the present disclosure;

FIG. 5 is a fourth structural diagram of a wafer dicing device in accordance with an example of the present disclosure;

FIG. 6 is a fifth structural diagram of a wafer dicing device in accordance with an example of the present disclosure;

FIG. 7 is a sixth structural diagram of a wafer dicing device in accordance with an example of the present disclosure;

FIG. 8 is a first top view of a bearing platform in accordance with an example of the present disclosure;

FIG. 9 is a second top view of a bearing platform in accordance with an example of the present disclosure; and

FIG. 10 is a flowchart of a method of wafer dicing in accordance with an example of the present disclosure.

### DETAILED DESCRIPTION

Hereinafter, example implementations disclosed by the present disclosure will be described in more detail with reference to accompanying drawings. Although example implementations of the present disclosure are illustrated in accompanying drawings, it should be understood that the present disclosure can be embodied in various forms and is not limited to specific implementations described herein. On the contrary, the implementations are provided for more thorough understanding of the present disclosure and to convey the scope disclosed by the present disclosure fully to those skilled in the art.

In the description hereafter, many specific details are provided to facilitate more thorough understanding of the present disclosure. However, it is apparent for those skilled in the art that the present disclosure can be implemented without one or more of these details. In other examples, in order not to obscure the present disclosure, some technical features well known in the art will not be described. That is to say, not all features of practical examples will be described herein and well-known functions and structures will not be described in detail.

In accompanying drawings, dimensions and relative sizes of layers, regions and elements may be exaggerated for clearance. The same reference numerals refer to the same elements throughout the specification.

It should be appreciated that when an element or a layer is said to be “over”, “adjacent to”, “connected to” or “coupled to” another element or layer, it may be directly over, adjacent to, connected to or coupled to the other element or layer or an intervening element or layer may exist therebetween. On the contrary, when an element is said to be “directly on”, “directly adjacent to”, “directly connected to” or “directly coupled to” another element or layer, there is no intervening element or layer therebetween. It should be appreciated that although various elements, components, regions, layers and/or parts may be described using terms “first”, “second”, “third” or the like, they are not limited by those terms. The terms are only used to distinguish one element, component, region, layer or part from another element, component, region, layer or part. Therefore, a first element, component, region, layer or part discussed hereafter may be instead expressed as a second element, component, region, layer or part without departing from the teaching of the present disclosure. When a second element, component, region, layer or part is in discussion, it is not intended to indicate that a first element, component, region, layer or part must exist.

Spatially relative terms, such as “below”, “beneath”, “lower”, “under”, “over” and “above”, are used herein for ease of description to explain the relationship of one element or feature with other elements or features as shown in the figures. It should be appreciated that, in addition to the orientations shown in the figures, different orientations of devices in use and operation are also intended to be covered by those spatially relative terms. For example, if a device is turned upside down, the element or feature described to be “beneath”, “under” or “below” another element or feature will have the orientation of being “over” the other element or feature. Therefore, example terms “beneath” and “under” may include orientations of both “below” and “above”. Devices may be otherwise oriented (rotated 90 degrees or at other orientations) and the spatially relative descriptors used herein may likewise be interpreted accordingly.

Terminology is used herein only for description of specific examples and in no way for limiting the present disclosure. As used herein, the terms “a”, “an” and “the” in singular forms are also intended to cover plural forms, unless the context clearly indicates otherwise. It is also be appreciated that terms “comprise”, “comprising”, “include” and/or “including”, as used in the specification, specify presence of the mentioned features, integers, steps, operations, elements and/or components, but do not exclude presence or addition of one or more other features, integers, steps, operations, elements, components and/or combinations thereof. As used herein, the term “and/or” includes any and all combinations of relevant listed items.

In order to disclose characteristics and technical contents of examples of the present disclosure more thoroughly, implementations of examples of the present disclosure will be described in detail hereafter with reference to accompanying drawings, which are only for reference and illustration and not for definition of examples of the present disclosure.

With increasing demands for semiconductor devices of higher degrees of integration, wafer dicing faces many challenges.

With the rapid development of the electronics industry, there are increasing demands for semiconductor devices of low costs and high performance. The degree of integration of a conventional 2D or planar memory is mainly determined by the area occupied by a unit memory cell. Therefore, the degree of integration of a conventional 2D or planar memory is largely constrained by the technology for formation of fine patterns. However, expensive processes and equipment are needed to increase fineness of the patterns, which greatly constrains the degree of integration of a conventional 2D or planar memory. 3D memory devices are an emerging type of flash memories developed in the industry, in which multiple tiers of data storage cells are stacked vertically to overcome the limitations of 2D or planar flash memories. 3D memory devices have excellent precision, enable higher capacity within a smaller footprint, have low costs and power consumption, and can fully satisfy various demands.

Wafer dicing is a crucial part in a semiconductor fabrication process. In order to reduce the influence on mechanical strength of the chips by scribing or dicing during the dicing process, a stealth dicing before grinding (SDBG) process is employed, in which the wafer is first cleaved along a dicing street through stealth dicing and then ground from backside, so as to obtain a chip with a predetermined thickness while removing mechanical damages caused by the stealth dicing process.

However, with the increasing demands for higher degrees of integration of semiconductor devices, a 3D memory device has to include a higher number of tiers stacked therein, a thickness of the 3D memory device is larger, and more complex metal layer structures is disposed in the dicing street. The metal layer structures contain a large amount of tungsten, which as a metal material hinders the wafer to be diced from cleaving in the specified direction through the SDBG process and causes cracks, chipping or breakage of chips, lowering the yield of chips. In order to solve the above-mentioned problems, in some examples, the wafer to be diced would be diced using laser dicing from front side and back side respectively and, due to the limitation of existing wafer dicing devices, the wafer to be diced can only be diced from the front side at first and then turned over to be diced from the back side using the wafer dicing device. In this way, there are problems of low dicing efficiency and great difficulty of aligning the dicing positions on the front side and the back side.

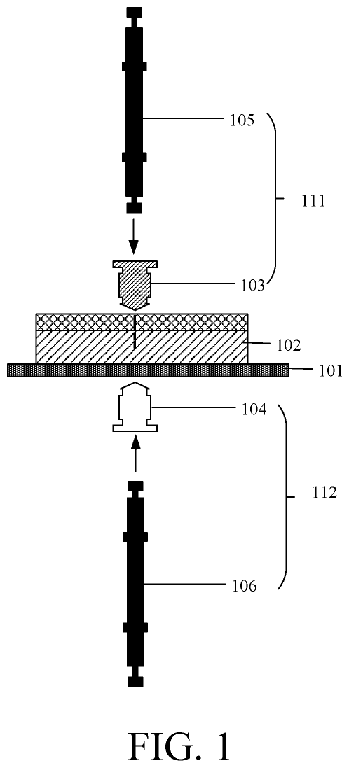

In view of one or more of the above-mentioned problems, examples of the present disclosure provide a wafer dicing device. As shown in FIG. 1, the wafer dicing device includes:
a bearing platform 101, a first dicing sub device 111 and a second dicing sub device 112; wherein,
the bearing platform 101 is configured to bear a wafer to be diced 102,
the first dicing sub device 111 is configured to dice the wafer to be diced 102 from a first side; and
the second dicing sub device 112 is configured to dice the wafer to be diced 102 from a second side, the first side and the second side being opposite sides of the bearing platform 101 in a first direction, the first direction being a direction of the thickness of the bearing platform 101.

In some specific examples, as shown in FIG. 1, the first direction is the vertical direction, the first side is the upper side of the bearing platform 101 and the second side is the lower side of the bearing platform 101, however the first and second sides are not limited to this.

In some specific examples, the wafer to be diced 102 may be, for example, a wafer having gone through all the processes in the phase of wafer processing, for example, the phase of forming device structures and interconnect structures thereof. The wafer to be diced 102 may include a semiconductor substrate and chips arranged in an array on the semiconductor substrate. The chips may include device structures and interconnect structures thereof. The device structures may include at least one of an active device and a passive device. For example, the active device may include a MOS device, a memory device or any other semiconductor device and the memory device may include, for example, a non-volatile memory, a random memory or the like. For example, the non-volatile memory may include floating-gate field effect transistors of at least one of a 3D NAND memory and a 3D NOR memory, or may include a dynamic random-access memory, a ferroelectric memory, a phase change memory or the like. The passive device may include, for example, a resistor, a capacitor or an inductor. The device structures may be a planar device or a three-dimensional device and the three-dimensional device may be, for example, a FIN-FET or a 3D memory.

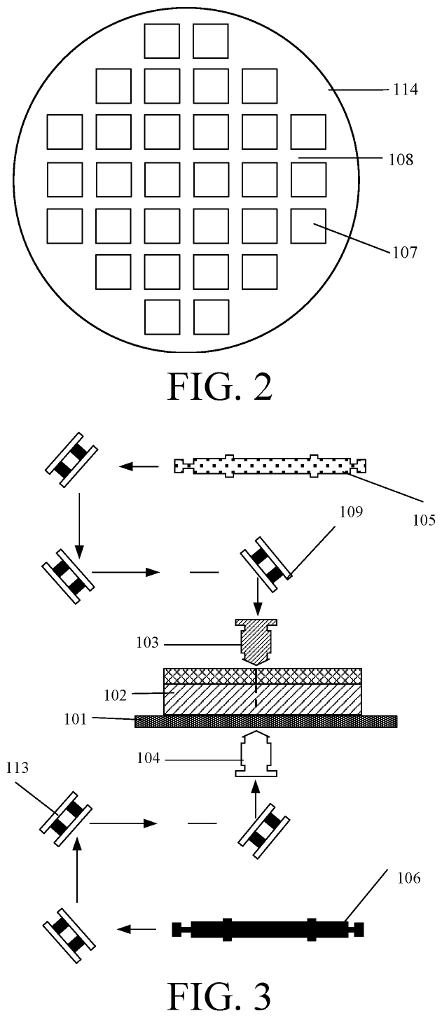

In some specific examples, as shown in FIG. 2, the wafer to be diced 102 includes a semiconductor substrate 114 and a plurality of chips 107 on the semiconductor substrate 114. The plurality of chips 107 are spaced apart from one another with dicing street 108 that may be arranged vertically and horizontally, i.e. disposed between rows and columns of the array of chips. The dicing street 108 are not configured to form actually used devices but mainly configured to dice the chips.

In some specific examples, the semiconductor substrate 114 may include silicon (e.g. single crystal silicon, c-Si), silicon germanium (SiGe), gallium arsenide (GaAs), germanium (Ge), silicon on insulator (SOI) or any other suitable material.

In some specific examples, the wafer to be diced 102 may have a diameter of 150 mm, 200 mm, 300 mm, 450 mm, etc., but not limited to this.

In the examples of the present disclosure, both the first dicing sub device and the second dicing sub device may be configured to perform the types of dicing, such as, but not limited to, laser dicing, blade dicing and plasma dicing. In some specific examples, the first dicing sub device and the second dicing sub device can perform the same type of dicing or different types of dicing. In an example, both the first dicing sub device and the second dicing sub device may be configured to perform laser dicing or blade dicing, or one of the first dicing sub device and the second dicing sub device is configured to perform laser dicing and the other is configured to perform blade dicing.

In some examples, both the first dicing sub device and the second dicing sub device are configured to perform laser dicing.

In some examples, as shown in FIG. 1, the first dicing sub device includes a first focusing lens 103 located on the first side and the second dicing sub device includes a second focusing lens 104 located on the second side, the first focusing lens 103 and the second lens 104 being aligned in the first direction when dicing the wafer to be diced 102.

Here, the first focusing lens 103 and the second focusing lens 104 being aligned in the first direction may be understood as the line connecting the first focusing lens 103 and the second focusing lens 104 being parallel to the direction of the thickness of the bearing platform 101.

It can be understood that the first focusing lens 103 and the second focusing lens 104 of the wafer dicing device provided in examples of the present disclosure are located on opposite sides of the bearing platform 101 respectively and the first focusing lens 103 and the second focusing lens 104 are aligned in the direction of the thickness of the bearing platform 101 during dicing, such that, when dicing the wafer from both the front side and the back side simultaneously, the dicing positions on the front side and the back side may be better aligned.

Here, the front side and the back side of the wafer to be diced 102 refer to the opposite sides of the wafer to be diced 102 in the direction of its thickness. In some specific examples, the front side of the wafer to be diced 102 is the side, on which elements, stack layers, wirings and pads are formed on the semiconductor substrate.

How to align the first focusing lens 103 and the second focusing lens 104 in the first direction will be introduced specifically hereafter and two implementations are provided in the present disclosure.

### A First Implementation:

In some examples, positions of the first focusing lens 103 and the second focusing lens 104 in the wafer dicing device are unmovable, and the first focusing lens 103 and the second focusing lens 104 are aligned in the first direction.

It can be understood that, the positions of the first focusing lens 103 and the second focusing lens 104 in the wafer dicing device are fixed and the first focusing lens 103 and the second focusing lens 104 are aligned in the first direction, such that the dicing positions on the front side and the back side are aligned when dicing the wafer from both the front side and the back side simultaneously. The alignment is achieved by fixing the positions of the first focusing lens 103 and the second focusing lens 104 in the wafer dicing device, such that the errors caused by adjusting the relative positions of the first focusing lens 103 and the second focusing lens 104 frequently can be reduced and the extra amount of work required for this adjustment can be omitted.

### A Second Implementation:

In some examples, the positions of the first focusing lens 103 and the second focusing lens 104 in the wafer dicing device are movable, and the first focusing lens 103 and the second focusing lens 104 can be aligned in the first direction by adjusting the positions of the first focusing lens 103 and the second focusing lens 104 when dicing the wafer to be diced 102.

It can be understood that the positions of the first focusing lens 103 and the second focusing lens 104 in the wafer dicing device may be not fixed, and the first focusing lens 103 and the second focusing lens 104 can be aligned under the control from a computer during the dicing process. The positions of the first focusing lens 103 and the second focusing lens 104 in the wafer dicing device are movable, such that the positions of the first focusing lens 103 and the second focusing lens 104 are not limited and the relative position between the first focusing lens 103 and the second focusing lens 104 can be adjusted based on actual requirements. This may be more flexible and satisfy more dicing requirements.

When the wafer to be diced 102 is being diced, the first focusing lens 103 performs the dicing to the wafer to be diced 102 by a first laser beam and the second focusing lens 104 performs the dicing to the wafer to be diced 102 by a second laser beam. The examples of the present disclosure provide several implementations on how to supply the first and second laser beams.

Firstly, for the lasers supplying the first and second laser beams, either the first and second laser beams may be supplied by two lasers respectively, or supplied together by one and the same laser.

In some examples, the first dicing sub device further includes a first laser 105 configured to supply the first laser beam to the first focusing lens 103; and
the second dicing sub device further includes a second laser 106 configured to supply the second laser beam to the second focusing lens 104.

In some examples, the first dicing sub device and the second dicing sub device each further include a first laser 105 that is configured to supply the first laser beam to the first focusing lens 103 and the second laser beam to the second focusing lens 104.

In some specific examples, the laser beam emitted by the first laser 105 may be divided into two laser beams and then supplied to the first focusing lens 103 and the second focusing lens 104 respectively.

When the first and second laser beams are supplied by the first laser 105 and the second laser 106 respectively, there are several cases with respect to the positions of the first laser 105 and the second laser 106. Positions of the first laser 105 and the second laser 106 will be introduced specifically hereafter.

As shown in FIGS. 1, 3 and 4, the first laser 105 and the second laser 106 may be located on the first side and the second side respectively.

In some examples, as shown in FIG. 1, the first laser 105 is located on the first side to be aligned with the first focusing lens 103 in the first direction and the second laser 106 is located on the second side to be aligned with the second focusing lens 104 in the first direction.

Here, the first laser 105 being aligned with the first focusing lens 103 in the first direction and the second laser 106 being aligned with the second focusing lens 104 in the first direction may be understood as the line connecting the light outlet of the first laser 105 and the light inlet of the first focusing lens 103 being parallel to the direction of thickness of the bearing platform 101 and the line connecting the light outlet of the second laser 106 and the light inlet of the second focusing lens 104 being parallel to the direction of thickness of the bearing platform 101.

It can be understood that the first laser 105 is aligned with the first focusing lens 103 in the first direction and the second laser 106 is aligned with the second focusing lens 104 in the first direction such that the laser beam generated by the first laser 105 hit the first focusing lens 103 directly and the laser beam generated by the second laser 106 hit the second focusing lens 104 directly. Thereby, in a first aspect, the length of the path, along which the generated laser beam travels to the focusing lens is relatively short and the energy loss during laser propagation over long path can be reduced; in a second aspect, the number of the structural components constituting the wafer dicing device is reduced.

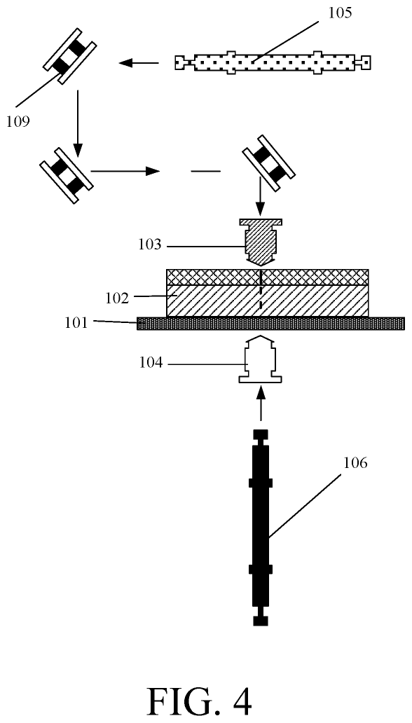

In some other examples, at least one of the following exists: the first laser 105 may not be aligned with the first focusing lens 103 at the first direction, or the second laser 106 may not be aligned with the second focusing lens 104 at the first direction. As shown in FIGS. 3 and 4, in at least one of the following cases: the first laser 105 is not aligned with the first focusing lens 103 at the first direction, or the second laser 106 is not aligned with the second focusing lens 104 at the first direction, a member for optical path conversion may be provided to direct the first laser beam into the first focusing lens and the second laser beam into the second focusing lens.

In examples of the present disclosure, the member for optical path conversion includes mirrors. Specifically, the he member for optical path conversion includes first mirrors 109 and second mirrors 113. The first mirrors 109 let the first laser beam enter the first focusing lens 103 and the second mirrors 113 let the second laser beam enter the second focusing lens 104.

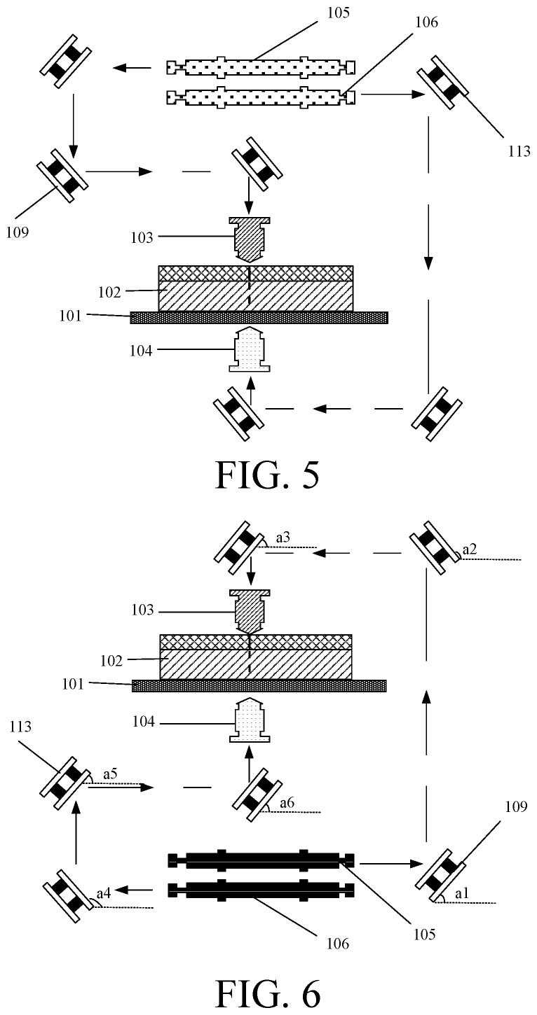

In some examples, both the first laser 105 and the second laser 106 are located on the first side, as shown in FIG. 5, or on the second side, as shown in FIG. 6.

The first dicing sub device further includes at least one first mirror 109 configured to direct the first laser beam generated by the first laser 105 into the first focusing lens 103; and
the second dicing sub device further includes at least one second mirror 113 configured to direct the second laser beam generated by the second laser 106 into the second focusing lens 104.

It is to be noted that, as shown in FIGS. 5 and 6, the first laser 105 and the second laser 106 emit laser beams in opposite directions that are both perpendicular to the first direction; and the first dicing sub device includes three first mirrors 109 and the second dicing sub device includes three second mirrors 113. However, the relative positions of the first laser 105 and the second laser 106 and the numbers of the first mirrors 109 and the second mirrors 113 are not limited to those described above. In some specific examples, the numbers and positions of the first mirrors and the second mirrors can be configured according to directions of the optical paths of the first and second laser beams emitted by the first and second lasers, as long as the first laser beam and the second laser beams can enter the first focusing lens 103 and the second focusing lens 104 respectively to enable the dicing of the wafer to be diced.

With FIG. 6 taken as an example, configuration of the first and second mirrors will be described specifically hereafter. In FIG. 6, there are three first mirrors 109. The first laser beam is emitted from the first laser 105 in the horizontal direction toward the right and has its optical path turn upward vertically with the first one of the first mirrors. Since the angle of incidence is equal to the angle of reflection, the first one of the first mirrors may be disposed at an angle a1 of 45° with respect to the horizontal direction. Subsequently, the optical path of the first laser beam is changed from pointing upward vertically to pointing toward the left in the horizontal direction by the second one of the first mirrors. Likewise, the second one of the first mirrors may be disposed at an angle a2 of 135° with respect to the horizontal direction. Then the first laser beam has its optical path turn downward vertically with the third one of the first mirrors and enters the first focusing lens. Similarly, the third one of the first mirrors may be disposed at an angle a3 of 45° with respect to the horizontal direction. The second mirrors can be disposed in a similar way to the first mirrors. The first one of the second mirrors is at an angle a4 of 135° with respect to the horizontal direction, the second one of the second mirrors is at an angle a5 of 45° with respect to the horizontal direction and the third one of the second mirrors is at an angle a6 of 45° with respect to the horizontal direction, such that the second laser beam is directed into the second focusing lens.

It can be understood that by disposing the first laser 105 and the second laser 106 on the same side, the height of the wafer dicing device can be reduced, in case the wafer dicing device is too high to be mounted and used.

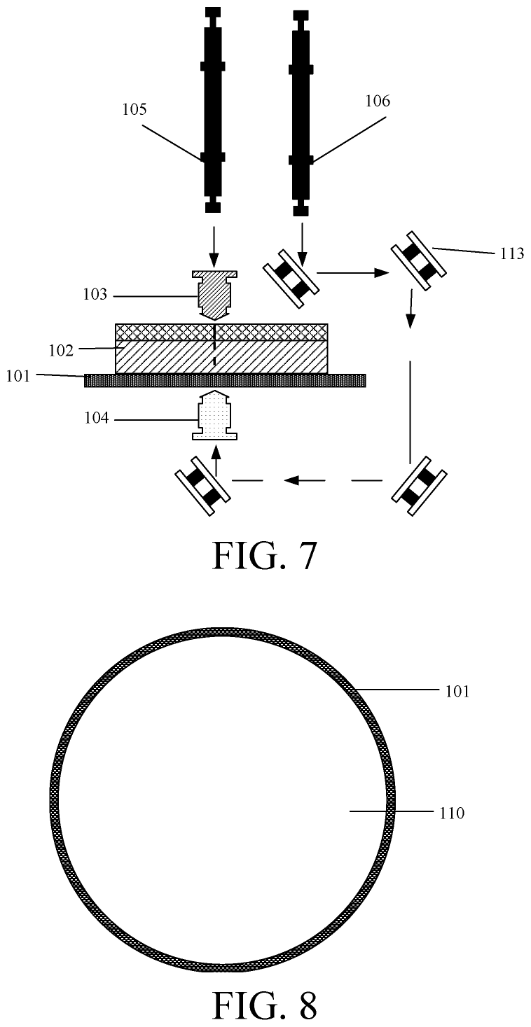

As shown in FIG. 7, the height of the wafer dicing device and simplification of its structural components can be taken into account comprehensively to dispose the first laser 105 and the second laser 106 on the same side, such that both of the laser beams emitted from the first laser 105 and the second laser 106 point downward vertically with the first laser beam generated by the first laser 105 entering the first focusing lens 103 directly and the second laser beam generated by the second laser 106 being directed by the second mirrors 113 into the second focusing lens 104.

It is to be noted that FIGS. 1, 3 and 7 are only examples and not intended to limit the first and second dicing sub devices in examples of the present disclosure. The first and second dicing sub devices as shown in FIGS. 1, 3 and 7 may be used in combination where there are no collisions.

In examples of the present disclosure, the wavelength of the first laser beam may be the same as or different from that of the second laser beam. In an example, if there are more metal layers on the front side and more dielectric layers on the back side of the wafer to be diced, a laser beam of a shorter wavelength can be chosen to dice the wafer from the front side and a laser beam of a longer wavelength can be chosen to dice the wafer from the back side. In practical applications, choices can be made according to the materials of the wafer to be diced on the front side and the back side.

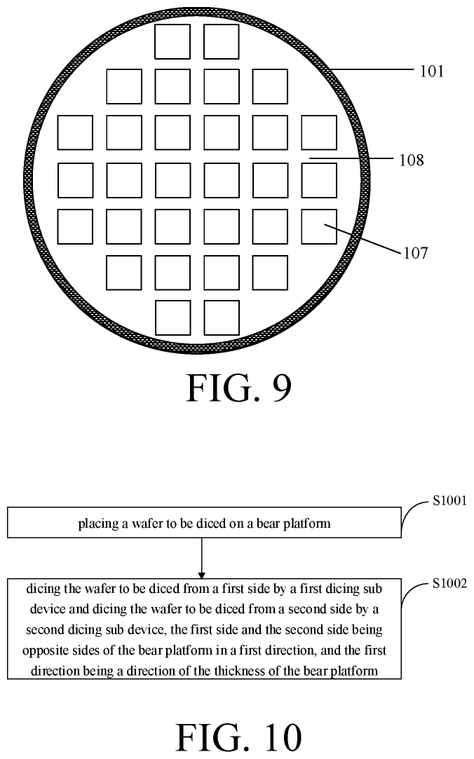

In examples of the present disclosure, in addition to improvement with respect to other components of the wafer dicing device, the bearing platform 101 can also be configured correspondingly. FIGS. 8 and 9 are top views of a bearing platform 101 provided in examples of the present disclosure. It is to be noted that in order to illustrate the relationship between the bearing platform 101 and the wafer to be diced 102, FIG. 9 shows a perspective view showing that the bearing platform 101 is actually below the wafer to be diced 102.

In some examples, as shown in FIG. 8, the bearing platform 101 has an opening 110 disposed therein, and as shown in FIG. 9, the opening 110 would expose the dicing street 108 of the wafer to be diced when the wafer to be diced is placed on the bearing platform 101.

It can be understood that the bearing platform 101 has an opening 110 disposed therein to exposes the dicing street 108 of the wafer to be diced, so that the dicing of the wafer to be diced on the back side will not be influenced by the dicing of the wafer to be diced on the front side.

In some examples, the position of the bearing platform 101 in the wafer dicing device is movable. During dicing of the wafer to be diced 102, the wafer to be diced 102 is diced at different positions by moving the bearing platform 101.

The requirements for dicing of heterogeneous integration structures are diverse and complex in the future. However, the wafer dicing device in examples of the present disclosure can dice the wafer to be diced 102 from the front side and the back side simultaneously and thus can satisfy a wider range of demands for dicing, for example, the demands for dicing as the number of stacked layers of chips increases can be met.

Examples of the present disclosure provide a wafer dicing device, including: a bearing platform 101, a first dicing sub device and a second dicing sub device, wherein the bearing platform 101 is configured to bear the wafer to be diced 102, the first dicing sub device 111 is configured to dice the wafer to be diced 102 from a first side; the second dicing sub device 112 is configured to dice the wafer to be diced 102 from a second side; the first side and the second side being opposite sides of the bearing platform 101 in a first direction, the first direction being a direction of the thickness of the bearing platform 101. In examples of the present disclosure, the wafer dicing device includes a first dicing sub device and a second dicing sub device that are respectively configured to dice the wafer to be diced 102 from both sides in the direction of the thickness of the bearing platform 101. In an aspect, the wafer dicing device in examples of the present disclosure enables the wafer to be diced 102 to be diced from the front side and the back side simultaneously, so as to increase the dicing efficiency. In another aspect, since the wafer to be diced 102 can be diced from both the front side and the back side simultaneously, components of the first and second dicing sub devices can be disposed correspondingly to reduce the difficulty of aligning the dicing positions on the front side and the back side when dicing the wafer to be diced 102 separately from the front side and the back side respectively, thus increasing the yield of the chip after cutting.

Based on the wafer dicing device above, examples of the present disclosure further provide a method of wafer dicing. As shown in FIG. 10, the method includes:
operation S1001: placing a wafer to be diced on a bearing platform; and
operation S1002: dicing the wafer to be diced from a first side using a first dicing sub device and dicing the wafer to be diced from a second side using a second dicing sub device with the first side and the second side being the opposite sides of the bearing platform in a first direction, the first direction being a direction of the thickness of the bearing platform.

When the wafer to be diced is being diced, the first and second dicing sub devices may be configured to dice the wafer to be diced from the front side and the back side simultaneously to increase the dicing efficiency, and when dicing the wafer to be diced from the front side and the back side simultaneously, dicing is performed on the same position of the wafer to be diced from the front side and the back side simultaneously, thus improving alignment of the dicing positions on the front side and the back side.

In some examples, both of the first dicing sub device and the second dicing sub device are configured to perform laser dicing.

In some examples, the first dicing sub device includes a first focusing lens located on the first side and the second dicing sub device includes a second focusing lens located on the second side; and
the operation of dicing the wafer to be diced from the first side using the first dicing sub device and dicing the wafer to be diced from the second side using the second dicing sub device includes:
aligning the first focusing lens and the second focusing lens in the first direction when dicing the wafer to be diced.

The present disclosure provides two implementations for aligning the first focusing lens and the second focusing lens in the first direction when dicing the wafer to be diced.

### A First Implementation:

In some examples, aligning the first focusing lens and the second focusing lens in the first direction includes:
setting positions of the first focusing lens and the second focusing lens to be unmovable in the wafer dicing device and aligning the first focusing lens and the second focusing lens in the first direction. Here, the positions of the first and second focusing lenses are not adjusted when dicing the wafer to be diced.

### A Second Implementation,

In some examples, aligning the first focusing lens and the second focusing lens in the first direction includes:
setting positions of the first focusing lens and the second focusing lens to be movable in the wafer dicing device and adjusting the positions of the first focusing lens and the second focusing lens to align the first focusing lens and the second focusing lens in the first direction when dicing the wafer to be diced.

In some examples, the first dicing sub device further includes a first laser and the second dicing sub device further includes a second laser; and
dicing the wafer to be diced from the first side using the first dicing sub device and dicing the wafer to be diced from the second side using the second dicing sub device includes:
supplying a first laser beam to the first focusing lens using the first laser to dice the wafer to be diced from the first side and supplying a second laser beam to the second focusing lens using the second laser to dice the wafer to be diced from the second side.

In some examples, the first dicing sub device and the second dicing sub device each further include a first laser;
dicing the wafer to be diced from the first side using the first dicing sub device and dicing the wafer to be diced from the second side using the second dicing sub device includes:
supplying a first laser beam to the first focusing lens using the first laser to dice the wafer to be diced from the first side and supplying a second laser beam to the second focusing lens using the first laser to dice the wafer to be diced from the second side.

In some examples, the position of the bearing platform in the wafer dicing device is movable;
dicing the wafer to be diced from the first side using the first dicing sub device and dicing the wafer to be diced from the second side using the second dicing sub device includes:
moving the bearing platform to dice the wafer to be diced at different positions when dicing the wafer to be diced.

It can be understood that “one example” or “an example” mentioned throughout the specification means that particular features, structures or characteristics in association with the example may be included in at least one example. Therefore, “in one example” or “in an example” mentioned throughout the specification refers not necessarily to the same example. Moreover, those particular features, structures or characteristics may be incorporated in one or more examples in any suitable manner. It can be understood that, in various examples of the present disclosure, the ordinal numbers of the various processes above are not intended to indicate that the processes must be performed in any sequential order and the various processes should be performed in a sequential order determined depending on their functions and inherent logic. Implementation of examples of the present disclosure is not limited in this respect. The ordinal numbers in the above-mentioned examples of the present disclosure are only for the purpose of description and imply no preference for any one or more examples over the others.

Wherever no collisions will occur, the methods disclosed in the several method examples provided by the present disclosure can be combined arbitrarily to obtain new method examples.

In accordance with a first aspect of examples of the present disclosure, a wafer dicing device is provided, which includes: a bearing platform, a first dicing sub device and a second dicing sub device, wherein
the bearing platform is configured to bear a wafer to be diced;
the first dicing sub device is configured to dice the wafer to be diced from a first side; and
the second dicing sub device is configured to dice the wafer to be diced from a second side, the first side and the second side being opposite sides of the bearing platform in a first direction, the first direction being a direction of a thickness of the bearing platform.

In the implementation above, the first dicing sub device and the second dicing sub device are configured to perform laser dicing.

In the implementation above, the first dicing sub device includes a first focusing lens located on the first side and the second dicing sub device includes a second focusing lens located on the second side, the first focusing lens and the second lens being aligned in the first direction when dicing the wafer to be diced.

In the implementation above, positions of the first focusing lens and the second focusing lens in the wafer dicing device are unmovable, and the first focusing lens and the second focusing lens are aligned in the first direction.

In the implementation above, positions of the first focusing lens and the second focusing lens in the wafer dicing device are movable and can be aligned in the first direction by adjusting the positions of the first focusing lens and the second focusing lens when dicing the wafer to be diced.

In the implementation above, the first dicing sub device further includes a first laser configured to supply a first laser beam to the first focusing lens; and
the second dicing sub device further includes a second laser configured to supply a second laser beam to the second focusing lens.

In the implementation above, the first dicing sub device and the second dicing sub device each further include a first laser that is used supply a first laser beam to the first focusing lens and a second beam to the second focusing lens.

In the implementation above, the first laser is located on the first side and aligned with the first focusing lens in the first direction and the second laser is located on the second side and aligned with the second focusing lens in the first direction.

In the implementation above, the first laser and the second laser are each located on the first side, or the first laser and the second laser are each located on the second side;
the first dicing sub device further includes at least one first mirror configured to direct the first laser beam generated by the first laser into the first focusing lens; and
the second dicing sub device further comprises at least one second mirror configured to direct the second laser beam generated by the second laser into the second focusing lens.

In the implementation above, the bearing platform has an opening disposed therein and the opening exposes a dicing street of the wafer to be diced when the wafer to be diced is placed on the bearing platform.

In the implementation above, a position of the bearing platform in the wafer dicing device is movable, and the wafer to be diced is diced at different positions by moving the bearing platform when dicing the wafer to be diced.

In accordance with a second aspect of examples of the present disclosure, a method of wafer dicing is provided, which includes:
placing a wafer to be diced on a bearing platform; and
dicing the wafer to be diced from a first side using a first dicing sub device and dicing the wafer to be diced from a second side using a second dicing sub device with the first side and the second side being the opposite sides of the bearing platform in a first direction, the first direction being a direction of a thickness of the bearing platform.

In the implementation above, the first dicing sub device and the second dicing sub device are configured to perform laser dicing.

In the implementation above, the first dicing sub device includes a first focusing lens located on the first side and the second dicing sub device includes a second focusing lens located on the second side; and
dicing the wafer to be diced from the first side using the first dicing sub device and dicing the wafer to be diced from the second side using the second dicing sub device includes:
aligning the first focusing lens and the second focusing lens in the first direction when dicing the wafer to be diced.

In the implementation above, aligning the first focusing lens and the second focusing lens in the first direction includes:
setting positions of the first focusing lens and the second focusing lens to be unmovable in the wafer dicing device and aligning the first focusing lens and the second focusing lens in the first direction, wherein the positions of the first and second focusing lenses are not adjusted when dicing the wafer to be diced.

In the implementation above, aligning the first focusing lens and the second focusing lens in the first direction includes:
setting positions of the first focusing lens and the second focusing lens to be movable in the wafer dicing device and adjusting the positions of the first focusing lens and the second focusing lens such that the first focusing lens and the second focusing lens are aligned in the first direction when dicing the wafer to be diced.

In the implementation above, the first dicing sub device further includes a first laser and the second dicing sub device further includes a second laser; and
dicing the wafer to be diced from the first side using the first dicing sub device and dicing the wafer to be diced from the second side using the second dicing sub device includes:
supplying a first laser beam to the first focusing lens using the first laser to dice the wafer to be diced from the first side and supplying a second laser beam to the second focusing lens using the second laser to dice the wafer to be diced from the second side.

In the implementation above, the first focusing lens and the second focusing lens further include a first laser; and
dicing the wafer to be diced from the first side using the first dicing sub device and dicing the wafer to be diced from the second side using the second dicing sub device includes:
supplying a first laser beam to the first focusing lens using the first laser to dice the wafer to be diced from the first side and supplying a second laser beam to the second focusing lens using the first laser to dice the wafer to be diced from the second side.

In the implementation above, a position of the bearing platform in the wafer dicing device is movable; and
dicing the wafer to be diced from the first side using the first dicing sub device and dicing the wafer to be diced from the second side using the second dicing sub device includes:
moving the bearing platform to dice the wafer to be diced at different positions when dicing the wafer to be diced.

What have been described above are only specific implementations of the present disclosure. However, the scope of the present disclosure is not limited thereto, and variations or substitutions that easily occur to those skilled in the art in light of the technical contents disclosed by the present disclosure will fall within the scope of the present disclosure. Therefore, the scope of the present disclosure should be determined by the scope of the claims.

What is claimed is:

1. A wafer dicing device, comprising: a bearing platform, a first dicing sub device and a second dicing sub device, wherein:
the bearing platform is configured to bear a wafer to be diced;
the first dicing sub device is configured to dice the wafer to be diced from a first side; and
the second dicing sub device is configured to dice the wafer to be diced from a second side, the first side and the second side being opposite sides of the bearing platform in a first direction, and the first direction being a direction of a thickness of the bearing platform.

2. The wafer dicing device of claim 1, wherein both of the first dicing sub device and the second dicing sub device are configured to perform laser dicing.

3. The wafer dicing device of claim 1, wherein the first dicing sub device comprises a first focusing lens located on the first side, and the second dicing sub device comprises a second focusing lens located on the second side, the first focusing lens and the second lens being aligned in the first direction when dicing the wafer to be diced.

4. The wafer dicing device of claim 3, wherein positions of the first focusing lens and the second focusing lens in the wafer dicing device are unmovable, and the first focusing lens and the second focusing lens are aligned in the first direction.

5. The wafer dicing device of claim 3, wherein positions of the first focusing lens and the second focusing lens in the wafer dicing device are movable, and the first focusing lens and the second focusing lens are aligned in the first direction by adjusting the positions of the first focusing lens and the second focusing lens when dicing the wafer to be diced.

6. The wafer dicing device of claim 3, wherein the first dicing sub device further comprises a first laser configured to supply a first laser beam to the first focusing lens; and
the second dicing sub device further comprises a second laser configured to supply a second laser beam to the second focusing lens.

7. The wafer dicing device of claim 3, wherein the first dicing sub device and the second dicing sub device each further comprise a first laser that is configured to supply a first laser beam to the first focusing lens and a second laser beam to the second focusing lens.

8. The wafer dicing device of claim 6, wherein the first laser is located on the first side and the second laser is located on the second side; wherein the first laser is aligned with the first focusing lens in the first direction and the second laser is aligned with the second focusing lens in the first direction.

9. The wafer dicing device of claim 6, wherein both the first laser and the second laser are located on the first side, or the second side;
the first dicing sub device further comprises at least one first mirror configured to direct the first laser beam generated by the first laser into the first focusing lens; and
the second dicing sub device further comprises at least one second mirror configured to direct the second laser beam generated by the second laser into the second focusing lens.

10. The wafer dicing device of claim 1, wherein the bearing platform has an opening disposed therein, and the opening exposes a dicing street of the wafer to be diced when the wafer to be diced is placed on the bearing platform.

11. The wafer dicing device of claim 1, wherein a position of the bearing platform in the wafer dicing device is movable, and the wafer to be diced is diced at different positions by moving the bear platform when dicing the wafer to be diced.

12. A method of wafer dicing, comprising:
placing a wafer to be diced on a bearing platform; and
dicing the wafer to be diced from a first side by a first dicing sub device; and
dicing the wafer to be diced from a second side by a second dicing sub device, the first side and the second side being opposite sides of the bearing platform in a first direction, and the first direction being a direction of a thickness of the bearing platform.

13. The method of claim 12, wherein both of the first dicing sub device and the second dicing sub device are configured to perform laser dicing.

14. The method of claim 12, wherein the first dicing sub device comprises a first focusing lens located on the first side, and the second dicing sub device comprises a second focusing lens located on the second side; and
dicing the wafer to be diced from the first side by the first dicing sub device and dicing the wafer to be diced from the second side by the second dicing sub device comprises:
aligning the first focusing lens and the second focusing lens in the first direction when dicing the wafer to be diced.

15. The method of claim 14, wherein the aligning the first focusing lens and the second focusing lens in the first direction comprises:
setting positions of the first focusing lens and the second focusing lens to be unmovable in the wafer dicing device and aligning the first focusing lens and the second focusing lens in the first direction, wherein the positions of the first focusing lens and the second focusing lens are not adjusted when dicing the wafer to be diced.

16. The method of claim 14, wherein the aligning the first focusing lens and the second focusing lens in the first direction comprises:
setting positions of the first focusing lens and the second focusing lens to be movable in the wafer dicing device and adjusting the positions of the first focusing lens and the second focusing lens such that the first focusing lens and the second focusing lens are aligned in the first direction when dicing the wafer to be diced.

17. The method of claim 14, wherein the first dicing sub device further comprises a first laser and the second dicing sub device further comprises a second laser; and
dicing the wafer to be diced from the first side by the first dicing sub device and dicing the wafer to be diced from the second side by the second dicing sub device comprises:
supplying a first laser beam to the first focusing lens by the first laser to dice the wafer to be diced from the first side and supplying a second laser beam to the second focusing lens by the second laser to dice the wafer to be diced from the second side.

18. The method of claim 14, wherein the first dicing sub device and the second dicing device each further comprise a first laser; and
dicing the wafer to be diced from the first side by the first dicing sub device and dicing the wafer to be diced from the second side by the second dicing sub device comprises:
supplying a first laser beam to the first focusing lens by the first laser to dice the wafer to be diced from the first side and supplying a second laser beam to the second focusing lens by the first laser to dice the wafer to be diced from the second side.

19. The method of claim 12, wherein a position of the bearing platform in the wafer dicing device is movable; and
dicing the wafer to be diced from the first side by the first dicing sub device and dicing the wafer to be diced from the second side by the second dicing sub device comprises:
moving the bearing platform to dice the wafer to be diced at different positions when dicing the wafer to be diced.
